(19) United States
(12) Patent Application Publication
(10) Pub. No.: US 2018/0212101 A1
(43) Pub. Date: Jul. 26, 2018

(54) LIGHT-EMITTING DEVICE

(71) Applicant: PIONEER CORPORATION, Tokyo (JP)

(72) Inventor: Hideo OCHI, Kawasaki-shi, Kanagawa (JP)

(21) Appl. No.: 15/738,925

(22) PCT Filed: Jul. 1, 2015
(86) PCT No.: PCT/JP2015/069059

§ 371 Date: Apr. 4, 2018

(51) Int. Cl. H01L 33/20; H01L 51/00; H01L 33/56; H01L 33/42

(52) U.S. Cl. CPC H01L 33/20; H01L 51/0008; H01L 33/42; H01L 33/56; H01L 51/0097

(57) ABSTRACT

A light-emitting device (10) includes a first base material (100), a second base material (200), a light-emitting element (300) and a control unit (400). The first base material (100) has flexibility and holds the light-emitting element (300). The control unit (400) controls the light-emitting element (300). The second base material (200) has flexibility and forms a partitioned space between the first base material (100) and itself by being partially fixed to the first base material (100). The control unit (400) is located in the space. A material of the second base material (200) has higher flexibility than that of the first base material (100).

### TECHNICAL FIELD

The present invention relates to a light-emitting device.

### BACKGROUND ART

An organic EL element is one example of a light source in a light-emitting device. Since the organic EL element has a light-emitting layer formed of organic matter, use of a flexible substrate allows the organic EL element to have flexibility. Meanwhile, the light-emitting device includes, other than the organic EL element and its substrate, other members such as a holding member to hold the organic EL element and the substrate. These other members also need flexibility for the light-emitting device itself to be flexible. For example, Patent Document 1 discloses providing a thin portion in a light-guiding plate used in a lighting device to allow the light-guiding plate to be bendable.

Meanwhile, Patent Document 2 discloses installing a belt-like supporter on the back of a lighting device to allow the lighting device to be worn on the back of the hand.

### RELATED ART DOCUMENTS

### Patent Documents

[Patent Document 1]: Japanese Unexamined Patent Application Publication No. 2012-169144

[Patent Document 2]: Japanese Unexamined Patent Application Publication No. 2013-145658

### SUMMARY OF THE INVENTION

### Problem to be Solved by the Invention

As described above, the light-emitting device includes the holding member which holds the light-emitting element such as an organic EL element and its substrate. In order for the light-emitting device to be flexible, the holding member needs to be flexible. To provide the holding member with flexibility, the holding member maybe formed of a flexible material. However, when the light-emitting device is bent, a stress is generated in a joint portion between the substrate of the light-emitting element and the holding member, and the stress may possibly be applied to the light-emitting element.

An example of the problem to be solved by the present invention is to reduce a stress applied to a light-emitting element when bending the light-emitting element, a substrate of the light-emitting element, and a holding member holding the substrate of the light-emitting element by providing the holding member with flexibility.

### Means for Solving the Problem

The invention described in claim 1 is a light-emitting device including:

a first base material having flexibility;

a light-emitting element held by the first base material;

a control unit controlling the light-emitting element;

a second base material having flexibility which forms a partitioned space between the first base material and itself by being partially fixed to the first base material,

in which the control unit is located in the space, and

in which a material of the second base material has higher flexibility than a material of the first base material.

### BRIEF DESCRIPTION OF THE DRAWINGS

The objects described above, and other objects, features and advantages are further made apparent by suitable embodiments that will be described below and the following accompanying drawings.

FIG. 1 is a top view illustrating a light-emitting device according to an embodiment.

FIG. 2 is a plan view illustrating a second base material included in the light-emitting device.

FIG. 3 is a cross-sectional view taken along line A-A of FIG. 1.

FIG.4 is a cross-sectional view of a curved light-emitting device.

FIG. 5 is a cross-sectional view illustrating a configuration of a light-emitting device according to Modification Example 1.

FIG. 6 is a plan view illustrating a light-emitting device illustrated in FIG. 5.

FIG. 7 is a cross-sectional view illustrating a configuration of a light-emitting device according to Modification Example 2.

FIG. 8 is a cross-sectional view illustrating a configuration of a light-emitting device according to Modification Example 3.

FIG. 9 is a cross-sectional view illustrating a configuration of a light-emitting device according to Modification Example 4.

FIG. 10 is a perspective view illustrating a configuration of a light-emitting device according to Modification Example 5.

FIG. 11 is a cross-sectional view taken along line B-B of FIG. 10.

FIG. 12 is a perspective view illustrating a configuration of a light-emitting device according to Modification Example 6.

FIG. 13 is a diagram illustrating how an auxiliary member is used.

FIG. 14 is a perspective view illustrating a configuration of a light-emitting device according to Modification Example 7.

### DESCRIPTION OF EMBODIMENTS

Hereinafter, embodiments of the present invention will be described with reference to the accompanying drawings. In all the drawings, like elements are referenced by like reference numerals and the descriptions thereof will not be repeated.

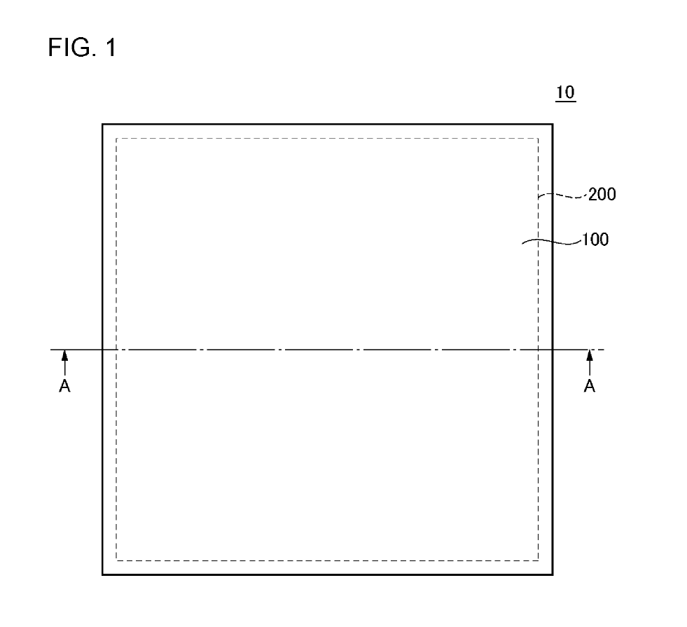

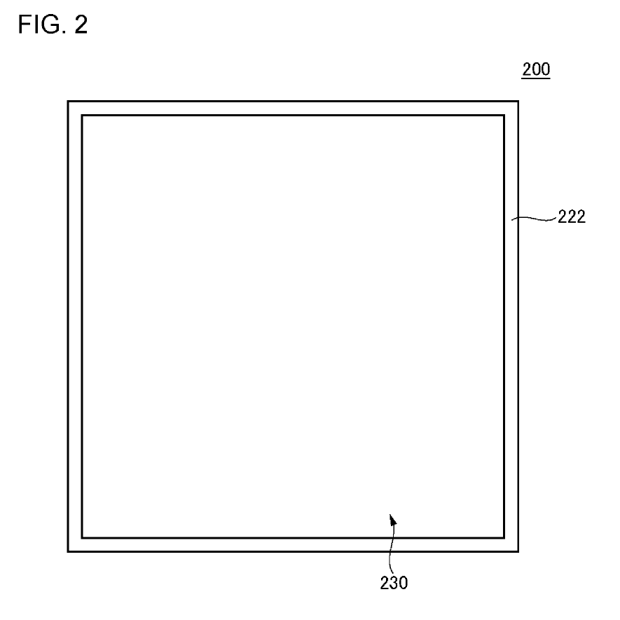

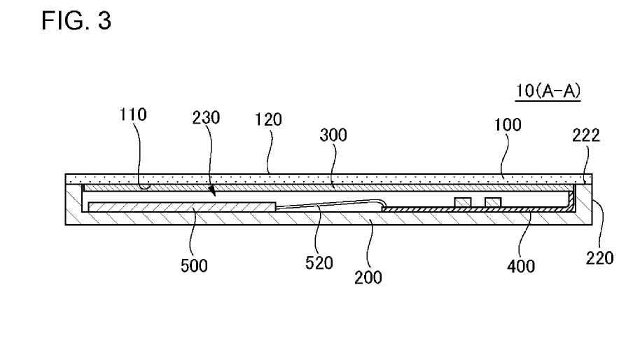

FIG. 1 is a top view illustrating a light-emitting device 10 according to an embodiment. FIG. 2 is a plan view illustrating a second base material 200 included in the light-emitting device 10. FIG. 3 is a cross-sectional view taken along line A-A of FIG. 1. The light-emitting device 10 according to the embodiment includes a first base material 100, the second base material 200, a light-emitting element 300, and a control unit 400. The first base material 100 has flexibility, and holds the light-emitting element 300. The control unit 400 controls the light-emitting element 300. The second base material 200 has flexibility and forms a partitioned space between the first base material 100 and itself by being partially fixed to the first base material 100. The control unit 400 and the light-emitting element 300 are located in this space. The material of the second base material 200 has higher flexibility than that of the first base material 100. A detailed description will be provided below.

The first base material 100 is used as a substrate of the light-emitting element 300. The first base material 100 is formed using, for example, a light-transmitting resin. For example, polyethylene naphthalate (PEN), polyether sulphone (PES), polyethylene terephthalate (PET), or polyimide may be used as the resin. The thickness of the first base material 100 is, for example, equal to or less than 200 μm. In addition, an inorganic barrier film such as a SiNₓ film, SiON film, or the like is formed at least on a surface of the first base material 100 having the light-emitting element 300 formed thereon (on a first surface 110, or preferably on both of the first surface 110 and a second surface 120) to inhibit moisture from permeating the first base material 100 and reaching the light-emitting element 300.

The light-emitting element 300 is, for example, an organic EL element, and includes a first electrode, a second electrode, and an organic layer.

The first electrode is a transparent electrode having optical transparency, and located on a light-emitting surface side of the light-emitting element 300. Materials of the transparent electrode are those containing a metal, for example, a metal oxide such as Indium Tin Oxide (ITO), Indium Zinc Oxide (IZO), Indium Tungsten Zinc Oxide (IWZO), Zinc Oxide (ZnO), or the like. The thickness of the first electrode is, for example, equal to or greater than 10 nm and equal to or less than 500 nm. The first electrode is formed, for example, by sputtering or vapor deposition. Meanwhile, the first electrode may be formed using a conductive organic material such as carbon nanotubes, PEDOT/PSS or the like. The first electrode may be provided with an auxiliary electrode. The auxiliary electrode is formed of, for example, MAM which is a laminated structure of Mo, Al, Mo alloy layers or the like in this order.

The second electrode includes, for example, a metal layer constituted of a metal selected from a first group consisting of Al, Au, Ag, Pt, Mg, Sn, Zn, and In, or an alloy of metals selected from the first group. In this case, the second electrode has light shielding properties. The thickness of the second electrode is, for example, equal to or greater than 10 nm and equal to or less than 500 nm. However, the second electrode may be formed using a material exemplified as the material of the first electrode. The second electrode is formed by, for example, sputtering or vapor deposition.

The organic layer is configured by laminating, for example, a hole injection layer, a light-emitting layer, and an electron injection layer in this order. A hole transporting layer may be formed between the hole injection layer and the light-emitting layer. In addition, an electron transporting layer maybe formed between the light-emitting layer and the electron injection layer. Moreover, a multiphoton structure containing multiple light-emitting layers may be included. In this case, a charge generating layer or an intermediate electrode formed of a material constituting the first electrode or the second electrode is provided between the light-emitting layers. The organic layer may be formed by vapor deposition. Further, at least one layer of the organic layer, for example, a layer in contact with the first electrode, may be formed by coating, such as ink jetting, printing, spraying or the like. Meanwhile, in this case, the remaining layers of the organic layer are formed by vapor deposition. In addition, all layers of the organic layer may be formed by coating.

Meanwhile, the light-emitting element 300 includes a first terminal and a second terminal. The first terminal is electrically connected to the first electrode, and the second terminal is electrically connected to the second electrode. These first and second terminals are electrically connected to the control unit 400.

The second base material 200 is polygonal such as, for example, rectangular, and includes a concave portion 230 on a surface (one surface) thereof facing the first base material 100. The concave portion 230 is provided for disposing the control unit 400 therein. At least a part of a portion of the one surface of the second base material 200 where the concave portion 230 is not formed is fixed to the first base material 100. In the example illustrated in FIG. 3, the second base material 200 has a configuration in which an entire periphery of the edge of a plate-like base material has a side 220 protruding toward the first surface 110 side. Meanwhile, there may be an area of the edge of the second base material 200 where the side 220 is not provided. An upper surface 222 of the side 220 is planar, and is fixed using an adhesive or the like to a part of the first surface 110 of the first base material 100 located around the light-emitting element 300. At least a part of a space for housing the control unit 400 (the entire space in the example shown in FIG. 3) is formed by the concave portion 230 of the first base material 100 and the second base material 200. Meanwhile, the surface of the first base material 100 holding the light-emitting element 300 faces the second base material 200. Therefore, the light-emitting element 300 is located in the space mentioned above.

The second base material 200 has flexibility and formed of a material having higher flexibility than that of the first base material 100. A material constituting the second base material 200 is, for example, a silicone resin or polyurethane.

The control unit 400 is configured of, for example, a microcomputer and other electrical elements installed on a circuit board. Here, the circuit board preferably has flexibility. However, for example, when the circuit board is small, the circuit board does not need to be flexible. The control unit 400 is, for example, placed or fixed on a surface of the second base material 200 facing the first base material 100.

Moreover, a battery 500 is housed in the space containing the control unit 400, that is, the space partitioned by the first base material 100 and the second base material 200. The battery 500 supplies electric power to the light-emitting element 300 through an interconnect 520 and the control unit 400. Meanwhile, the battery 500 preferably has flexibility. However, for example, when the battery 500 is small, the battery 500 does not need to be flexible.

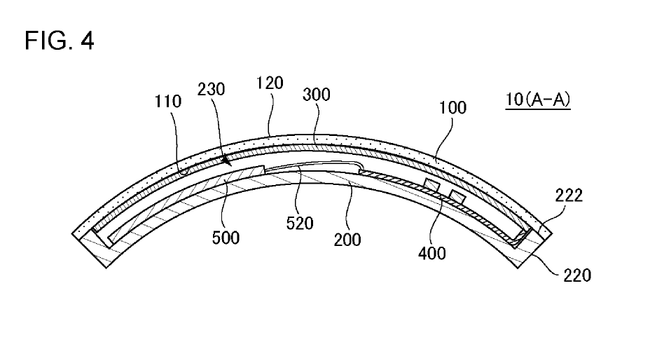

FIG. 4 is a cross-sectional view of a curved light-emitting device 10. When the light-emitting device 10 is curved, a stress is originated at a joint portion between the first base material 100 and the second base material 200 (specifically, a joint portion between the edge of the first base material 100 and the upper surface 222 of the side 220 of the second base material 200). The stress may cause a strain to occur in the first base material 100, and as a result, a stress may be applied to the light-emitting element 300. In contrast, according to the present embodiment, the side 220 of the second base material 200 is formed by a material softer than that of the first base material 100. Therefore, the stress applied to the first base material 100 may be reduced by deformation of the side 220. As a result, the stress applied to the light-emitting element 300 can be reduced.

Here, the light-emitting device 10 is preferably prevented from excessively bending by adjusting at least one of the thickness of the first base material 100 and that of the second base material 200. For example, to set the curvature of the light-emitting device 10 to a level where the light-emitting element 300 is not damaged when force of approximately 300N is applied to the light-emitting device 10, at least one of the thickness of the first base material 100 and that of the second base material 200 may be adjusted.

Meanwhile, in FIG. 4, the light-emitting device 10 is curved in a direction of a tensile stress applied to the first base material 100 (that is, in a projecting direction of the second surface 120 of the first base material 100). However, the light-emitting device 10 may be curved in the direction of a compressive stress applied to the first base material 100 (that is, in the recessing direction of the second surface 120).

### MODIFICATION EXAMPLE 1

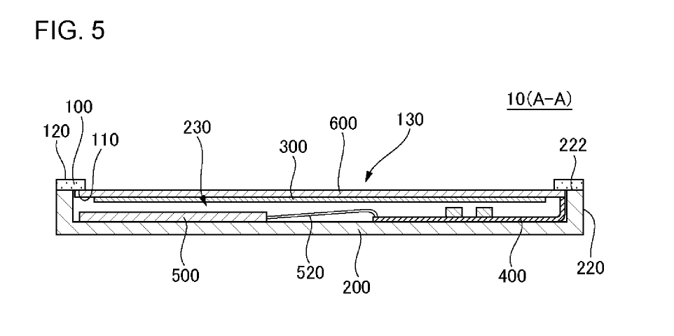

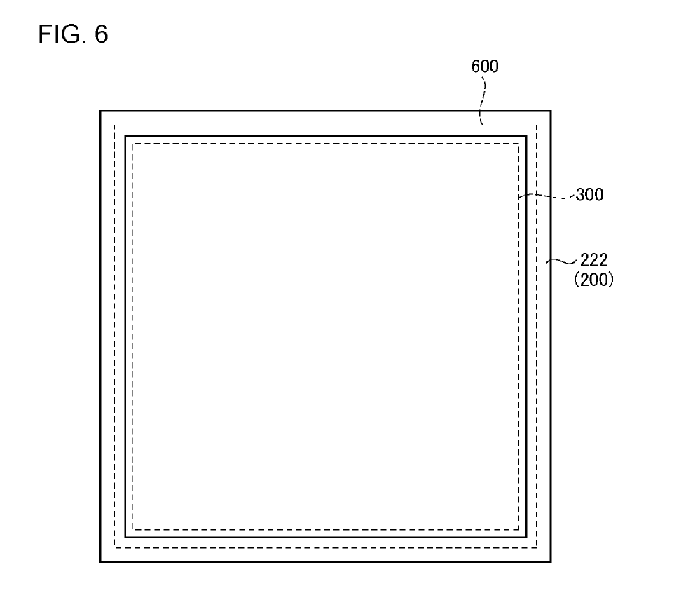

FIG. 5 is a cross-sectional view illustrating a configuration of the light-emitting device 10 according to Modification Example 1, and FIG. 6 is a plan view of the light-emitting device 10 illustrated in FIG. 5. FIG. 5 corresponds to FIG. 3 of the embodiment, and FIG. 6 corresponds to FIG. 1 of the embodiment. The light-emitting device 10 according to Modification Example 1 has the same configuration as the light-emitting device 10 according to the embodiment except the following points.

First, the light-emitting element 300 is formed on a third base material 600, instead of on the first base material 100. The third base material 600 is formed using, for example, PEN, PES, PET, or polyimide. The thickness of the third base material 600 is, for example, equal to or less than 200 μm.

In addition, the first base material 100 has a frame-like shape that is open except its rim. In other words, the first base material 100 includes an opening 130. A portion of the first surface 110 of the first base material located near the outer edge is fixed to the upper surface 222 of the side 220 of the second base material 200, and a portion of the first surface 110 of the first base material 100 located near the inner edge is fixed to the edge of a surface of the third base material 600 on a side opposite to the light-emitting element 300. Thus, at least apart of the opening 130 (the entire opening in the example of FIGS. 5 and 6) is covered by the third base material 600. Moreover, the light-emitting element 300 overlaps the opening 130.

Meanwhile, when the first base material 100 has translucency, the first base material 100 does not need to include the opening 130. In this case, the entire surface of the third base material 600 is fixed to the first surface 110 of the first base material 100.

The present example also reduces the stress applied to the light-emitting element 300 when the light-emitting device 10 is curved for the same reason as the embodiment.

Moreover, in the embodiment, since the light-emitting element 300 is formed on the first base material 100, high flatness and gas barrier properties are required in the first base material 100. Thus, manufacturing costs of the first base material 100 may be increased. In contrast thereto, in the present modification example, since the light-emitting element 300 is formed on the third base material 600, high flatness and gas barrier properties are required in the third base material 600. An area of the third base material 600 is smaller than that of the first base material 100 according to the embodiment. Therefore, manufacturing costs of the third base material 600 may be lower than those of the first base material 100 according to the embodiment. Meanwhile, high flatness and gas barrier properties may not be required in the first base material 100 according to the present modification example. Therefore, manufacturing costs of the first base material 100 according to the present modification example may be reduced. As a result, manufacturing costs of the light-emitting device 10 may be reduced compared to those of the embodiment.

### MODIFICATION EXAMPLE 2

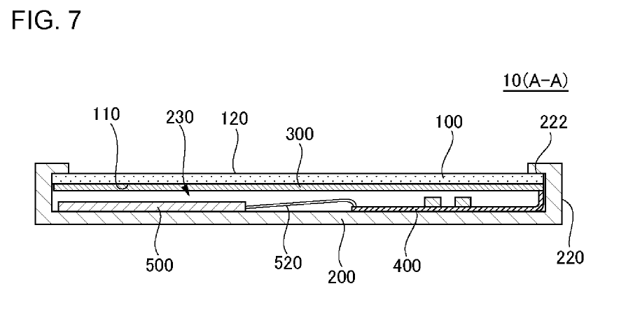

FIG. 7 is a cross-sectional view illustrating a configuration of the light-emitting device 10 according to Modification Example 2, and corresponds to FIG. 3 in the embodiment. The light-emitting device 10 according to the present modification example has the same configuration as the light-emitting device 10 according to the embodiment, except that an upper part of the side 220 of the second base material 200 is bent toward the inside of the light-emitting device 10, the upper part covering the edge of the second surface 120 of the first base material 100 and being fixed thereto. Meanwhile, in Modification Example 1, the side 220 may have the same configuration as that of Modification Example 2.

The stress applied to the light-emitting element 300 when the light-emitting device 10 is curved may be reduced also according to Modification Example 2 for the same reason as in the embodiment. Moreover, the light-emitting element 300 may be prevented from being damaged, since the second surface 120 of the first base material 100 is located further on the inner side of the light-emitting device 10 than the upper part of the side 220, and also a side face of the first base material 100 is covered by the side 220.

### MODIFICATION EXAMPLE 3

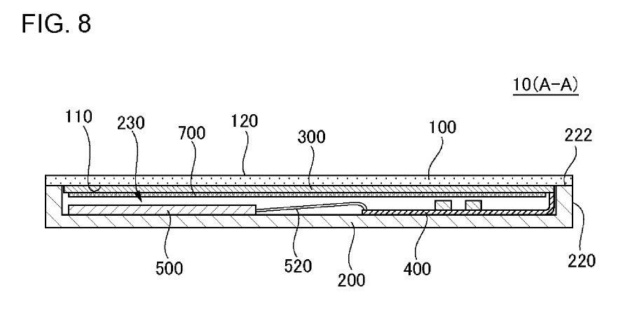

FIG. 8 is a cross-sectional view illustrating a configuration of the light-emitting device 10 according to Modification Example 3, and corresponds to FIG. 3 in the embodiment. The light-emitting device 10 according to Modification Example 3 has the same configuration as the light-emitting device 10 according to the embodiment except that a sheet-like member 700 is included in the space partitioned by the first base material 100 and the second base material 200.

The sheet-like member 700 is flexible and planar. The sheet-like member 700 is located between the control unit 400 and the battery 500, and the light-emitting element 300. Thus, the light-emitting element 300 may be prevented from being damaged in a case where the control unit 400 or the battery 500 contacts the light-emitting element 300 when bending the light-emitting device 10. A material constituting the sheet-like member 700, for example, PET or the like, is preferably harder (less elastic) than a material constituting the second base material 200.

Moreover, the present modification example may also reduce the stress applied to the light-emitting element 300 when the light-emitting device 10 is curved for the same reason as in the embodiment. Meanwhile, filling the space partitioned by the first base material 100 and the second base material 200 with resin having flexibility may be considered; however, the method disclosed in Modification Example 3 costs less and may reduce the weight of the light-emitting device 10.

Meanwhile, the light-emitting device 10 may include the sheet-like member 700 in Modification Examples 1 to 2.

### MODIFICATION EXAMPLE 4

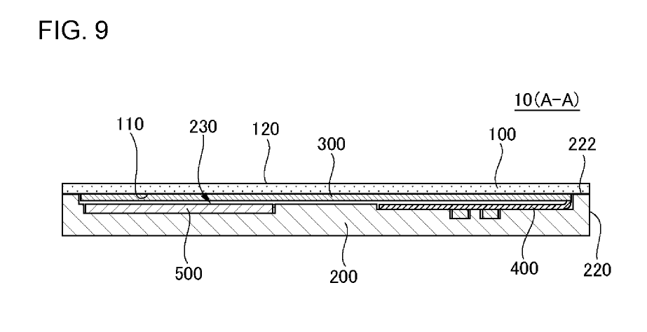

FIG. 9 is a cross-sectional view illustrating a configuration of the light-emitting device 10 according to Modification Example 4, and corresponds to FIG. 3 of the embodiment. The light-emitting device 10 according to Modification Example 4 has the same configuration as the light-emitting device 10 according to the embodiment except the following points.

First, a surface of the circuit board of the control unit 400 having a microcomputer and an element mounted thereon faces the second base material 200. Therefore, a planar one of the surfaces of the control unit 400 faces the light-emitting element 300. The concave portion 230 of the second base material 200 is formed corresponding to each of the battery 500 and the microcomputer or the element of the control unit 400. In other words, the concave portion 230 for housing the battery 500 and the concave portion 230 for housing the control unit 400 are formed independently of each other in the second base material 200.

The present modification example also may reduce the stress applied to the light-emitting element 300 when the light-emitting device 10 is curved may be reduced for the same reason as in the embodiment. Moreover, since the planar one of the surfaces of the control unit 400 faces the light-emitting element 300, the light-emitting element 300 may be prevented from being damaged by the control unit 400 when curving the light-emitting device 10.

Meanwhile, in Modification Examples 1 to 2, the concave portion 230 may have the same configuration as that of Modification Example 4.

### MODIFICATION EXAMPLE 5

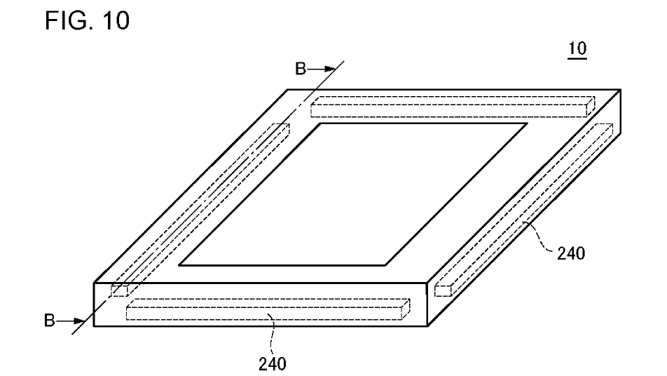

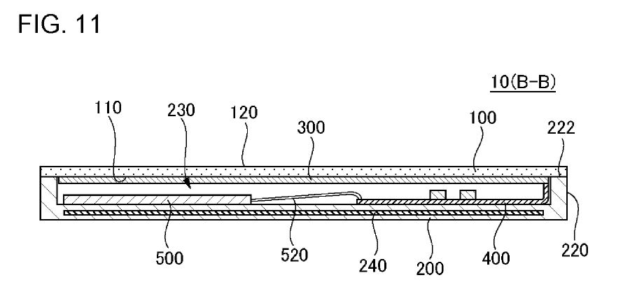

FIG. 10 is a perspective view illustrating a configuration of a light-emitting device 10 according to Modification Example 5, and FIG. 11 is a cross-sectional view taken along line B-B of FIG. 10. The light-emitting device 10 according to Modification Example 5 has the same configuration as that of the embodiment or any of Modification Examples 1 to 4, except that the light-emitting device 10 includes a shape retaining member 240. Meanwhile, FIG. 11 illustrates the same case as that of the embodiment.

The shape retaining member 240 is a bar-shaped member and is embedded in the lower portion of the side 220 of the second base material 200. The shape retaining member 240 is formed using a bendable material capable of maintaining a bent shape (for example, a metal material such as tin). In the example illustrated in FIG. 10, the second base material 200 is polygonal (for example, rectangular), and the shape retaining member 240 is provided along each side of the second base material 200. However, at least one side of the second base material 200 may not include the shape retaining member 240. Moreover, the shape retaining member 240 may be shaped so that portions thereof embedded in two sides of the second member 200 next to each other are connected (an L shape, for example) or may be shaped along the edges of the second base material (a rectangular frame when the second base material is rectangular).

Meanwhile, the shape retaining member 240 is embedded in the second base material 200 by, for example, being inserted into a hole provided in the second base material 200. In this case, a part (for example, a center part) of the shape retaining member 240 maybe fixed (for example, adhered) to the second base material 200. Alternatively, no part of the shape retaining member 240 is required to be fixed to the second base material 200. In this way, the second base material 200 remains easily bendable compared to a case where the entire shape retaining member 240 is fixed to the second base material 200.

The present modification example can reduce the stress applied to the light-emitting element 300 when the light-emitting device 10 is curved due to the same reason as the embodiment. Moreover, when the light-emitting device 10 is bent, the shape retaining member 240 is also bent, so that the light-emitting device 10 is able to retain its bent shape even when zero force is applied thereto.

### MODIFICATION EXAMPLE 6

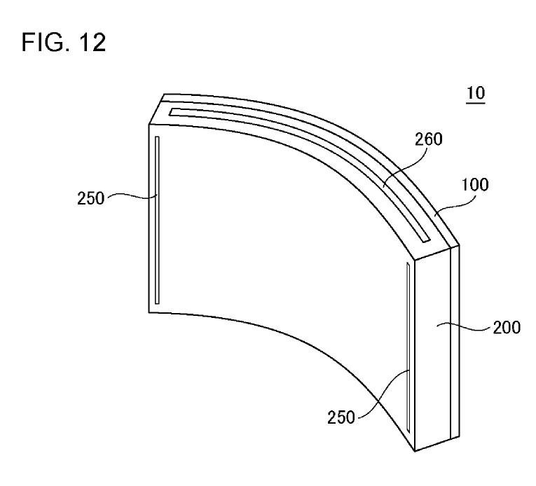

FIG. 12 is a perspective view illustrating a configuration of a light-emitting device 10 according to Modification Example 6. The light-emitting device 10 according to Modification Example 6 has the same configuration as that of the embodiment or any of Modification Examples 1 to 5, except the following points.

First, the second base material 200 includes two grooves 250 and a slit 260.

The two grooves 250 are formed in a surface of the second base material 200 opposite to the surface facing the first base material 100, being apart from each other. In the example illustrated in FIG. 12, the second base material 200 is polygonal, and the grooves 250 are formed along two opposite sides of the second base material 200.

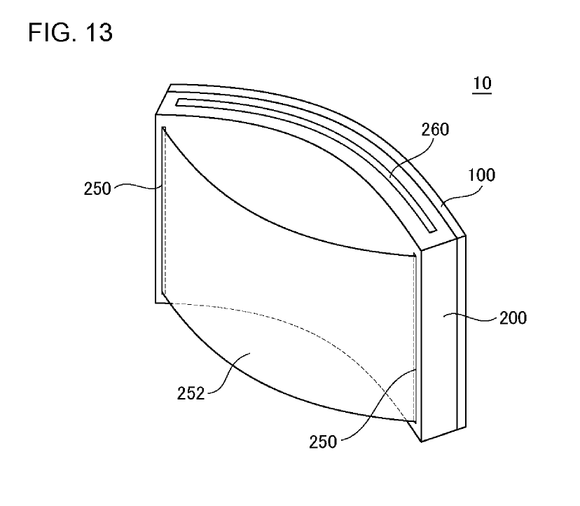

The slit 260 is formed in the side 220 of the second base material 200 and is capable of housing an auxiliary member 252 therein (see FIG. 13). Meanwhile, the slit 260 may pass through a part serving as the bottom plate of the second base material 200 or may be connected to the space partitioned by the first base material 100 and the second base material 200.

FIG. 13 illustrates how the auxiliary member 252 is used. The auxiliary member 252 is, as described above, housed in the slit 260 and taken out of the slit 260 for use. One end of the auxiliary member 252 is fixed to one of the grooves 250, and the other end of the auxiliary member 252 is fixed to the remaining groove 250. The width of the auxiliary member 252 is narrower than the interval between the grooves 250. Therefore, by fixing the auxiliary member 252 to the grooves 250, the light-emitting device 10 curves in a direction in which the first base material 100 projects outward. The usage mentioned above may be employed in a case where, for example, the light-emitting device 10 is a desktop lamp.

### MODIFICATION EXAMPLE 7

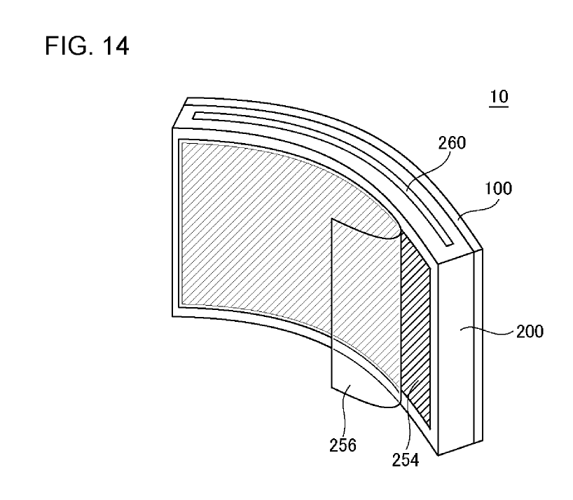

FIG. 14 is a perspective view illustrating a configuration of the light-emitting device 10 according to Modification Example 7. The light-emitting device 10 according to Modification Example 7 has the same configuration as that of Modification Examples 6, except the following points.

First, no groove 250 is provided in the second base material 200, and instead, an adhesive layer 254 is provided on a surface of the second base material 200 opposite to the surface thereof facing the first base material 100.

The adhesive layer 254 is provided in order to attach the light-emitting device 10 on a wall or the like. The adhesive layer 254 is covered by a protective sheet 256. The protective sheet 256 is peeled off from the adhesive layer 254 and then housed in the slit 260. Moreover, after the light-emitting device 10 is taken off from a wall or the like, the adhesive layer 254 is covered by the protective sheet 256 again. Such usage is employed when, for example, attaching and detaching the light-emitting device 10 to and from a wall or the like.

The embodiment and the examples are described above referring to the drawings, but these are examples of the present invention and various configurations other than those described above can be employed.

1. A light-emitting device comprising:
a first base material having flexibility;
a light-emitting element held by the first base material;
a control unit controlling the light-emitting element;
a second base material having flexibility which forms a partitioned space between the first base material and itself by being partially fixed to the first base material,
wherein the control unit is located in the space, and
wherein a material of the second base material has higher flexibility than flexibility of a material of the first base material.

2. The light-emitting device according to claim 1,
wherein the light-emitting element is located in the space.

3. The light-emitting device according to claim 1,
wherein the second base material includes a concave portion on a one surface side, and at least a part of a region of the one surface where the concave portion is not formed is fixed to the first base material, and
wherein at least a part of the space is the concave portion.

4. The light-emitting device according to claim 1,
wherein the first base material comprises an opening,
the light-emitting device further comprising a third base material covering at least a part of the opening,
wherein the light-emitting element is formed on the third base material and overlaps the opening.

5. The light-emitting device according to claim 1,
wherein the second base material comprises a side face portion erected toward the first base material provided on at least a part of an edge of the second base material,
wherein at least a part of an upper end of the side face portion is bent in a direction to cover the first base material, and
wherein an edge of a surface of the first base material not facing the space is covered by the bent part of the upper end of the side face portion.

6. The light-emitting device according to claim 1,
wherein the light-emitting element is located in the space, and
wherein the light-emitting device further comprises a flexible sheet-like member located between the light-emitting element and the control unit.
